(19) United States
(12) Patent Application Publication
(10) Pub. No.: US 2026/0173487 A1
(43) Pub. Date: Jun. 18, 2026

(54) SEMICONDUCTOR DEVICE AND METHOD FOR FABRICATING THE SAME

(71) Applicant: NANYA TECHNOLOGY CORPORATION, NEW TAIPEI CITY (TW)

(72) Inventor: YU-HUA LIU, NEW TAIPEI CITY (TW)

(21) Appl. No.: 18/981,769

(22) Filed: Dec. 16, 2024

(51) Int. Cl. H10D 64/66; H10D 30/01; H10D 30/60; H10D 64/01; H10D 64/27; H10D 64/68

(52) U.S. Cl. CPC H10D 64/679; H10D 30/601; H10D 64/514; H10D 64/517; H10D 64/661; H10D 64/665; H10D 64/693; H10D 30/0227; H10D 64/015; H10D 64/021

(57) ABSTRACT

The present application discloses a semiconductor device and a method for fabricating the same. The semiconductor device comprises a substrate, a gate structure, a spacer structure, and a sealing layer. The gate structure is positioned on the substrate. The spacer structure includes a first spacer, a second spacer, a third spacer, and an air gap. The first spacer is disposed on a sidewall of the gate structure, and the air gap is located between the first spacer and the second spacer. The air gap is enclosed by the first spacer, the second spacer, the third spacer, and the sealing layer.

### TECHNICAL FIELD

The present disclosure relates to a semiconductor device and a method for fabricating the same, and more particularly, to a semiconductor device including a spacer with an air gap and a method for fabricating the same.

### DISCUSSION OF THE BACKGROUND

Semiconductor devices are essential for many modern applications. With advancement of electronic technology, semiconductor devices are becoming smaller in size while providing greater functionality and including greater amounts of integrated circuitry. Due to the miniaturized scale of semiconductor devices, distinct types and dimensions of semiconductor devices providing different functionalities are integrated and packaged into a single module. Furthermore, numerous manufacturing operations are implemented for integration of such distinct types of semiconductor devices.

As devices are scaled down, parasitic capacitance between a gate and a contact increases, leading to increases in gate delay. To mitigate the increases in spacer capacitance, low-k materials can replace oxide and nitride in the spacers. The low-k materials have a lower dielectric constant, which helps reduce parasitic effects. Among the low-k materials, air gaps have the lowest permittivity and can be effectively used as spacer materials, thereby enhancing overall device performance and reliability.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device comprising a substrate with a top surface, a gate structure disposed on the top surface of the substrate, a spacer structure disposed on a sidewall of the gate structure, and a sealing layer covering the substrate, the spacer structure, and the gate structure. The spacer structure comprises a first spacer, a second spacer, a third spacer, and an air gap. The first spacer is disposed on the sidewall of the gate structure, and the air gap is located between the first spacer and the second spacer. The air gap is enclosed by the first spacer, the second spacer, the third spacer, and the sealing layer.

In some embodiments, the gate structure comprises a first dielectric layer disposed on the top surface of the substrate, a metallic compound layer disposed over the first dielectric layer, a second metallic layer disposed over the metallic compound layer, a third dielectric layer disposed on the second metallic layer, and a fourth dielectric layer covering the first dielectric layer, the metallic compound layer, the second metallic layer, and the third dielectric layer.

In some embodiments, the first dielectric layer includes silicon oxide; the metallic compound layer includes polysilicon; the second metallic layer includes tungsten; the third dielectric layer includes silicon nitride; and the fourth dielectric layer also includes silicon nitride.

In some embodiments, the semiconductor device further comprises a second dielectric layer disposed between the first dielectric layer and the metallic compound layer, and a first metallic layer disposed between the second dielectric layer and the metallic compound layer.

In some embodiments, the fourth dielectric layer further covers the second dielectric layer and the first metallic layer.

In some embodiments, the second dielectric layer includes hafnium oxide, hafnium aluminum oxide, hafnium silicate, tantalum oxide, aluminum oxide, zirconium oxide, the like, or a combination thereof; and the first metallic layer includes tungsten, aluminum, tantalum, titanium, platinum, nickel, or an alloy or a combination thereof.

In some embodiments, the air gap is sealed by the sealing layer.

In some embodiments, the air gap comprises a slanted bottom surface.

In some embodiments, the slanted bottom surface is coplanar with a slanted sidewall of the first spacer.

In some embodiments, a vertical sidewall of the air gap is coplanar with a vertical sidewall of the second spacer and a vertical sidewall of the third spacer.

In some embodiments, a lowest point of the air gap is located at a vertical level lower than a vertical level of a topmost point of the third spacer.

In some embodiments, the sealing layer includes silicon nitride.

In some embodiments, a distance between the air gap and the gate structure is positively correlated with a thickness of the fourth dielectric layer.

Another aspect of the present disclosure provides a semiconductor structure, comprising a substrate including a lightly doped drain (LDD) region disposed in a top surface of the substrate and a source/drain (S/D) region disposed in the substrate and adjacent to the LDD region, a gate structure disposed on the substrate, a spacer structure disposed on a sidewall of the gate structure, a sealing layer covering the substrate, the spacer structure, and the gate structure, a dielectric layer covering the sealing layer, and a contact disposed in the dielectric layer and extending into the S/D region. The spacer structure comprises a first spacer, a second spacer, a third spacer, and an air gap. The air gap is disposed between the first spacer and the second spacer. The air gap is sealed by the sealing layer. The air gap is enclosed by the first spacer, the second spacer, the third spacer, and the sealing layer.

In some embodiments, the gate structure comprises a first dielectric layer disposed on the top surface of the substrate, a second dielectric layer disposed over the first dielectric layer, a first metallic layer disposed over the second dielectric layer, a metallic compound layer disposed over the first dielectric layer, a second metallic layer disposed over the metallic compound layer, a third dielectric layer disposed on the second metallic layer, and a fourth dielectric layer covering the first dielectric layer, the first metallic layer, the second dielectric layer, the metallic compound layer, the second metallic layer and the third dielectric layer.

In some embodiments, the second dielectric layer includes hafnium oxide, hafnium aluminum oxide, hafnium silicate, tantalum oxide, aluminum oxide, zirconium oxide, the like, or a combination thereof; and the first metallic layer includes tungsten, aluminum, tantalum, titanium, platinum, nickel, or an alloy or a combination thereof.

In some embodiments, the air gap comprises a slanted bottom surface.

In some embodiments, the slanted bottom surface is coplanar with a slanted sidewall of the first spacer.

In some embodiments, a vertical sidewall of the air gap is coplanar with a vertical side surface of the second spacer and a vertical sidewall of the third spacer.

In some embodiments, a lowest point of the air gap is located at a vertical level lower than a vertical level of a topmost point of the third spacer.

In some embodiments, a distance between the air gap and the gate structure is positively correlated with a thickness of the fourth dielectric layer.

Another aspect of the present disclosure provides a method for fabricating a semiconductor device comprising providing a substrate; sequentially depositing a first dielectric material, a second dielectric material, a first metallic layer, a metallic compound material, a second metallic material, and a third dielectric material over and covering the substrate; performing a lithography process using a photoresist as a mask on the second dielectric material, the first metallic material, the metallic compound material, the second metallic material, and the third dielectric material, thereby forming a second dielectric layer, a first metallic layer, a metallic compound layer, a second metallic layer, and a third dielectric layer, respectively; depositing a fourth dielectric material covering the first dielectric material, the second dielectric layer, the first metallic layer, the metallic compound layer, the second metallic layer, and the third dielectric layer; forming a first dielectric layer and a fourth dielectric layer, wherein the first dielectric layer, the second dielectric layer, the first metallic layer, the metallic compound layer, the second metallic layer, the third dielectric layer and the fourth dielectric layer together configure a gate structure; conformally forming a fifth dielectric material over the fourth dielectric layer and the substrate; forming a sixth dielectric material over the fifth dielectric material; forming a seventh dielectric material over the sixth dielectric material; forming a first spacer structure on a sidewall of the gate structure, wherein the first spacer structure comprises a first spacer, a second spacer, and a third spacer, with the third spacer sandwiched between the first spacer and the second spacer; forming a second spacer structure on the sidewall of the gate structure by removing an upper portion of the first spacer structure; and conformally forming a sealing layer over the substrate, the second spacer structure, and the gate structure, wherein the sealing layer seals the air gap.

In some embodiments, prior to the formation of the sealing layer, the method further comprises performing a trimming process to remove a residual portion of the seventh dielectric material over the gate structure.

In some embodiments, the trimming process comprises an etch-back process.

In some embodiments, the second dielectric material includes hafnium oxide, hafnium aluminum oxide, hafnium silicate, tantalum oxide, aluminum oxide, zirconium oxide, the like, or a combination thereof.

In some embodiments, the formation of the second dielectric material is performed using an atomic layer deposition process.

In some embodiments, a thickness of the fifth dielectric material is positively correlated with a thickness of the fourth dielectric layer.

In some embodiments, a thickness of the sixth dielectric material is positively correlated with a deposition rate of the sealing layer.

Another aspect of the present disclosure provides a method for fabricating a semiconductor structure comprising providing a gate structure over a substrate; forming a lightly doped drain (LDD) region in the substrate; forming a spacer structure on a sidewall of the gate structure; forming a source/drain (S/D) region in the substrate; forming a dielectric layer covering the spacer structure and the gate structure; forming an opening in the dielectric layer, wherein the opening extends from a top surface of the dielectric layer and into the S/D region of the substrate; and forming a contact by depositing a conductive material in the opening. In some embodiments, the LDD region and the S/D region are formed by an ion implantation process.

In some embodiments, the contact is separated from the gate structure by the spacer structure.

Embodiments of the present disclosure provide a semiconductor device that includes a spacer structure comprising an air gap. Additionally, a method is presented for utilizing the spacer structure to reduce parasitic capacitance between a gate and a contact. By applying the semiconductor device and the associated method, parasitic capacitance between the gate and the contact is reduced, leading to improved gate performance.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a cross-sectional diagram of a semiconductor device in accordance with some embodiments of the present disclosure.

FIG. 1B is a cross-sectional diagram of a semiconductor structure in accordance with some embodiments of the present disclosure.

FIG. 2A is a flow diagram of a method for fabricating a semiconductor device in accordance with some embodiments of the present disclosure.

FIGS. 2B to 2S are schematic cross-sectional diagrams illustrating intermediate stages of a method for fabricating a semiconductor device in accordance with some embodiments of the present disclosure.

FIG. 3A is a flow diagram of a method for fabricating a semiconductor structure in accordance with some embodiments of the present disclosure.

FIGS. 3B to 3H are schematic cross-sectional diagrams illustrating intermediate stages of a method for fabricating a semiconductor structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures, do not necessarily mean an exactly identical orientation, layout, location, shape, size, amount, or other measure, but are intended to encompass nearly identical orientations, layouts, locations, shapes, sizes, amounts, or other measures within acceptable variations that may occur, for example, due to manufacturing processes. The term “substantially” may be used herein to reflect such meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the axis Z, and below (or down) corresponds to the opposite direction of the arrow of the axis Z.

It should be noted that, in the description of the present disclosure, the term “about,” when used to modify a quantity of an ingredient, component, or reactant of the present disclosure, refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or to carry out the methods, and the like. In one aspect, the term “about” means within 10% of the reported numerical value. In another aspect, the term “about” means within 5% of the reported numerical value. In yet another aspect, the term “about” means within 10%, 9%, 8%, 7%, 6%, 5%, 4%, 3%, 2% or 1% of the reported numerical value.

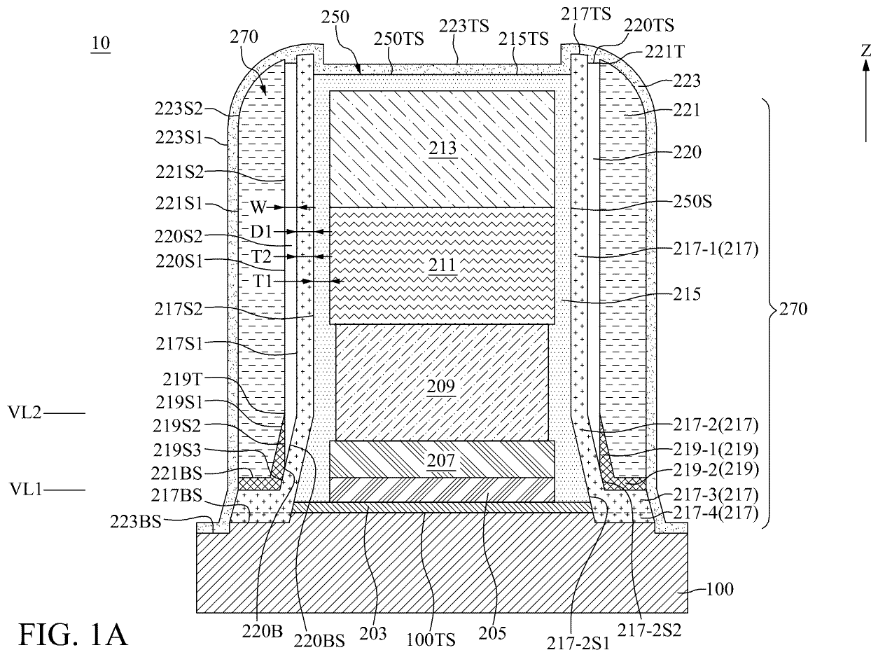

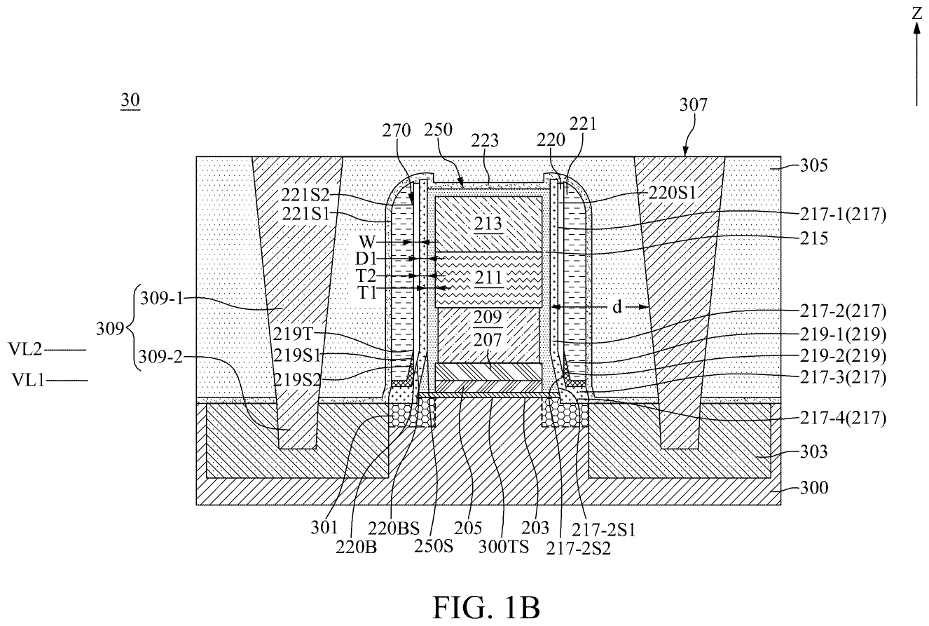

FIG. 1A is a cross-sectional diagram of a semiconductor device 10 in accordance with some embodiments of the present disclosure. The semiconductor device 10 may comprise a substrate 100, a gate structure 250, a spacer structure 270, and a sealing layer 223.

With reference to FIG. 1A, in some embodiments, the substrate 100 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or a combination thereof.

In some embodiments, the substrate 100 may include a semiconductor-on-insulator structure consisting of, from bottom to top, a handle substrate, an insulator layer, and a topmost semiconductor material layer. The handle substrate and the topmost semiconductor material layer may be formed of a material same as a material of the bulk semiconductor substrate mentioned above. The insulator layer may be a crystalline or non-crystalline dielectric material, such as an oxide and/or a nitride. For example, the insulator layer may be a dielectric oxide such as silicon oxide. Alternatively, the insulator layer may be a dielectric nitride such as silicon nitride or boron nitride. Additionally, the insulator layer may comprise a stack of a dielectric oxide and a dielectric nitride, such as a stack of silicon oxide, silicon nitride, and/or boron nitride, in any order.

With reference to FIG. 1A, the gate structure 250 may be layered over the substrate 100. In some embodiments, the gate structure 250 may include a dielectric layer 203 positioned on the substrate 100, a metallic compound layer 209 atop the dielectric layer 203, a metallic layer 211 above the metallic compound layer 209, a dielectric layer 213 over the metallic layer 211, and a dielectric layer 215 covering the dielectric layer 203, the metallic compound layer 209, the metallic layer 211, and the dielectric layer 213. In alternative embodiments, the gate structure 250 may also incorporate a dielectric layer 205 and a metallic layer 207 situated between the dielectric layer 203 and the metallic compound layer 209, with the metallic layer 207 positioned above the dielectric layer 205. In such embodiments, the dielectric layer 215 may also cover the dielectric layer 205 and the metallic layer 207. A top surface 215TS of the dielectric layer 215 may be referred to as the top surface 250TS of the gate structure 250.

In some embodiments, the dielectric layer 203 may be composed of a dielectric material, such as silicon oxide, silicon nitride, silicon oxynitride, low-k dielectric materials, the like, or a combination thereof. The low-k dielectric materials may have a dielectric constant of less than 3.0, or even less than 2.5. In some embodiments, the low-k dielectric materials may exhibit a dielectric constant less than 2.0. In some embodiments, the dielectric material may be formed by a deposition process, such as a chemical vapor deposition (CVD) process, followed by an etching process, which may include isotropic etching, anisotropic etching, or a combination thereof. A CVD process temperature typically ranges from 600° C. to 1000° C., and a process pressure is usually equal to or less than one atmospheric pressure (1 atm).

In some embodiments, the dielectric layer 205 may be composed of a high-k dielectric material (e.g., a dielectric material having a dielectric constant greater than 3.9 or 7.0). The high-k dielectric material may include hafnium oxide, hafnium aluminum oxide, hafnium silicate, tantalum oxide, aluminum oxide, zirconium oxide, or a combination thereof. In some embodiments, the dielectric material may be formed using deposition processes such as an atomic layer deposition (ALD) process, followed by an etching process, which may include isotropic etching, anisotropic etching, or a combination thereof. An ALD process temperature typically ranges from 50° C. to 300° C., and a process pressure usually ranges from a few millitorr (mTorr) to several tens of torr (Torr).

In some embodiments, the metallic layer 207 may be composed of a metallic material such as tungsten, titanium, titanium nitride, aluminum, or a combination thereof. In some embodiments, the metallic material may be formed by a deposition process and a subsequent etching process. In some embodiments, the deposition process may include a physical vapor deposition (PVD) process, a chemical vapor deposition (CVD) process, an atomic layer deposition (ALD) process, or a combination thereof. In some embodiments, the etching process may include isotropic etching, anisotropic etching, or a combination thereof.

In some embodiments, the metallic compound layer 209 may be composed of polysilicon, a metal silicide, polycide, or silicon carbide. The metal silicides may include titanium silicide (TiSi₂) or cobalt silicide (CoSi₂). In some embodiments, the metallic compound layer 209 may be formed using deposition processes such as a chemical vapor deposition (CVD) process or an atomic layer deposition (ALD) process, followed by an etching process, which may include isotropic etching, anisotropic etching, or a combination thereof.

In some embodiments, the metallic layer 211 may include tungsten, tantalum, aluminum, an alloy thereof (such as aluminum-copper or tungsten-tantalum), or a combination thereof. In some embodiments, the metallic layer 211 may be formed by a deposition process, such as a physical vapor deposition (PVD) process, followed by an etching process, which may include isotropic etching, anisotropic etching, or a combination thereof.

In some embodiments, the dielectric layer 213 may be composed of silicon nitride, silicon oxynitride, a low-k dielectric material, the like, or a combination thereof. The low-k dielectric material may have a dielectric constant less than 3.0 or even less than 2.5. In some embodiments, the low-k dielectric material may have a dielectric constant less than 2.0. In some embodiments, the dielectric layer 213 may be formed by a deposition process, such as a chemical vapor deposition (CVD) process, followed by an etching process, which may include isotropic etching, anisotropic etching, or a combination thereof.

In some embodiments, the dielectric layer 215 may be composed of a material same as a material of the dielectric layer 213. In other words, the dielectric layer 215 may also include silicon nitride, silicon oxynitride, a low-k dielectric material, the like, or a combination thereof. The low-k dielectric material may have a dielectric constant less than 3.0 or even less than 2.5. In some embodiments, the low-k dielectric material may have a dielectric constant less than 2.0. In some embodiments, the dielectric layer 215 may be formed by a deposition process, such as a chemical vapor deposition (CVD) process, followed by an etching process, which may include isotropic etching, anisotropic etching, or a combination thereof.

With reference to FIG. 1A, the spacer structure 270 may be positioned on a top surface 100TS of the substrate 100 and on a sidewall 250S of the gate structure 250. The spacer structure 270 may include spacers 217 and 219, an air gap 220, and a spacer 221.

In some embodiments, the spacer 217 may be conformally disposed on the sidewall 250S of the gate structure 250 and extend into the substrate 100. The spacer 217 may include a vertical portion 217-1 on the sidewall 250S of the gate structure 250, a slanted portion 217-2 under and connected to the vertical portion 217-1, and a horizontal portion 217-3 below the slanted portion 217-2 and connected to the slanted portion 217-2. In some embodiments, a portion 217-4 of the horizontal portion 217-3 of the spacer 217 may be disposed in the substrate 100. In some embodiments, the spacer 217 may include silicon oxide, silicon nitride, silicon oxynitride, organosilicate glass, polyimide, fluorinated silicate glass, or a combination thereof.

In some embodiments, the spacer 219 may be disposed over the spacer 217 and positioned between the spacer 217 and the spacer 221. The spacer 219 may include a portion 219-1 and a portion 219-2, with the portion 219-2 located below and connected to the portion 219-1. The portion 219-1 of the spacer 219 may be slanted and may include a topmost point 219T located at a vertical level VL2. The portion 219-2 of the spacer 219 may be horizontal and sandwiched between the spacer 217 and the spacer 221. In some embodiments, the spacer 219 may be composed of silicon oxide, silicon nitride, silicon oxynitride, organosilicate glass, polyimide, fluorinated silicate glass, or a combination thereof.

In some embodiments, the air gap 220 may be disposed between the spacer 217 and the spacer 221. The air gap 220 may be vertically oriented and sandwiched by the spacer 217 and the spacer 221. In some embodiments, the air gap 220 may connect to the spacer 219. The air gap 220 may include a slanted bottom surface 220BS and a lowest point 220B located at a vertical level VL1. In some embodiments, a sidewall 220S1 of the air gap 220 and a sidewall 219S2 of the spacer 219 may be coplanar. Additionally, the slanted bottom surface 220BS may be coplanar with a slanted sidewall 217-2S2 of the slanted portion 217-2 of the spacer 217. In some embodiments, the vertical level VL1 of the lowest point 220B of the air gap 220 may be lower than the vertical level VL2 of the topmost point 219T of the spacer 219.

In some embodiments, the spacer 221 may be disposed over the spacer 217 and separated from the spacer 217 by the spacer 219 and the air gap 220. A sidewall 221S2 of the spacer 221, the sidewall 220S1 of the air gap 220, and the sidewall 219S2 of the spacer 219 may be coplanar. In some embodiments, the spacer 221 may include silicon oxide, silicon nitride, silicon oxynitride, organosilicate glass, polyimide, fluorinated silicate glass, or a combination thereof.

With reference to FIG. 1A, the sealing layer 223 may be disposed to cover the substrate 100, the spacer structure 270, and the gate structure 250. The sealing layer 223 may seal the air gap 220. In other words, the air gap 220 may be enclosed by the spacers 217, 219, 221, and the sealing layer 223. In some embodiments, after the air gap 220 is sealed, the air gap 220 includes a top surface 220TS. In some embodiments, the top surface 220TS of the air gap 220 is lower than a top surface 217TS of the spacer 217 and is also lower than a topmost point 221T of the spacer 221. In some embodiments, the spacer 221 may include silicon oxide, silicon nitride, silicon oxynitride, organosilicate glass, polyimide, fluorinated silicate glass, or a combination thereof.

It should be noted that a width W of the air gap 220 is positively correlated with a deposition rate of the sealing layer 223. In other words, an increase in the deposition rate of the sealing layer 223 allows for a greater width W of the air gap 220, while a decrease in the deposition rate of the sealing layer 223 results in a smaller width W of the air gap 220. This design aims to prevent the sealing layer 223 from filling the air gap 220. Parameters of the deposition rate of the sealing layer 223 and the width W of the air gap 220 depend on design requirements of the process.

Additionally, a distance D1 between the air gap 220 and the gate structure 250 is positively correlated with a thickness T1 of the dielectric layer 215. In other words, an increase in the thickness T1 of the dielectric layer 215 allows for a greater distance D1, while a decrease in the thickness T1 of the dielectric layer 215 results in a smaller distance D1. This design aims to prevent the generation of parasitic capacitance, reduce gate delay, and achieve better gate control performance. Parameters of the thickness T1 of the dielectric layer 215 and the distance D1 between the air gap 220 and the gate structure 250 depend on the design requirements of the process.

FIG. 1B is a cross-sectional diagram of a semiconductor structure 30 in accordance with some embodiments of the present disclosure. The semiconductor structure 30 may include a substrate 300, a gate structure 250, a spacer structure 270, a sealing layer 223, a dielectric layer 305, and a contact 309.

With reference to FIG. 1B, in some embodiments, the substrate 300 may be similar to the substrate 100 shown in FIG. 1A, except that the substrate 300 may also include a lightly doped drain (LDD) region 301 and a source/drain (S/D) region 303. Materials of the substrate 300 may be same as those of the substrate 100, and repeated descriptions are omitted.

In some embodiments, the LDD region 301 is located below the gate structure 250, near a drain region (e.g., the source/drain (S/D) region 303) in the substrate 300, and in a channel region between the drain region and a source region (e.g., the source/drain (S/D) region 303). In some embodiments, the LDD region 301 may have a doping concentration lower than that of the source/drain (S/D) region 303, so as to reduce a strength of an electric field near the drain region. A dopant used in the LDD region 301 depends on a type of MOSFET (metal-oxide-semiconductor field-effect transistor) being formed. For example, in n-type MOSFETs, the substrate 300 is usually formed of n-type silicon, and the LDD region 301 uses lightly-doped n-type dopants such as phosphorus or arsenic. In contrast, in p-type MOSFETs, the substrate 300 is typically formed of p-type silicon, and the LDD region 301 uses lightly-doped p-type dopants such as boron.

In some embodiments, the source/drain (S/D) region 303 may be disposed near the LDD region 301. In some embodiments, the source/drain (S/D) region 303 and the LDD region 301 may partially overlap. A doping type of the source/drain (S/D) region 303 is typically same as that of the LDD region 301. A doping concentration in the source/drain (S/D) region 303 is typically higher than that in the LDD region 301. This means that the dopants used in the LDD region 301 (such as phosphorus or boron) are present at a lower concentration than dopants in the S/D region 303.

With reference to FIG. 1B, in some embodiments, the gate structure 250, the spacer structure 270 and the sealing layer 223 are same as those shown in FIG. 1A, and repeated descriptions are omitted. It should be noted that the sealing layer 223 may completely cover the substrate 300.

With reference to FIG. 1B, in some embodiments, the dielectric layer 305 may be disposed over and cover the sealing layer 223. In some embodiments, the dielectric layer 305 may include silicon oxide, silicon nitride, silicon oxynitride, organosilicate glass, polyimide, fluorinated silicate glass, or a combination thereof.

With reference to FIG. 1B, in some embodiments, the contact 309 may be located on a side of the gate structure 250 and spaced apart from the gate structure 250 by a distance of d. The contact 309 may penetrate the dielectric layer 305 and extend into the S/D region 303. In some embodiments, the contact 309 may be separated from the gate structure 250 by the spacer structure 270 and the sealing layer 223. The contact 309 may include an upper portion 309-1 disposed in the dielectric layer 305 and a lower portion 309-2 disposed in the S/D region 303. Both the upper portion 309-1 and the lower portion 309-2 may have a tapered profile. In some embodiments, the contact 309 may include aluminum, copper, tungsten, cobalt, gold, silver, an alloy (such as aluminum-copper alloy), or a combination thereof.

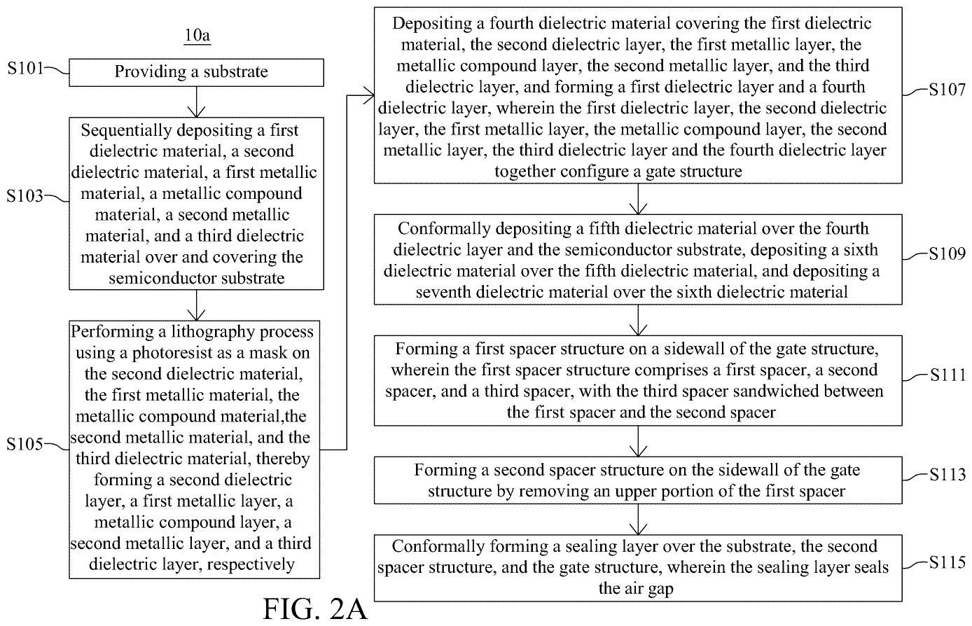

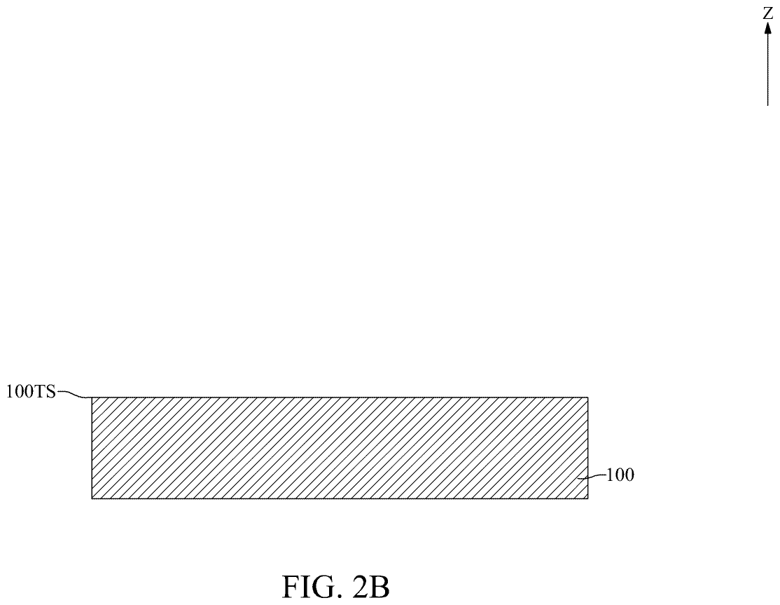

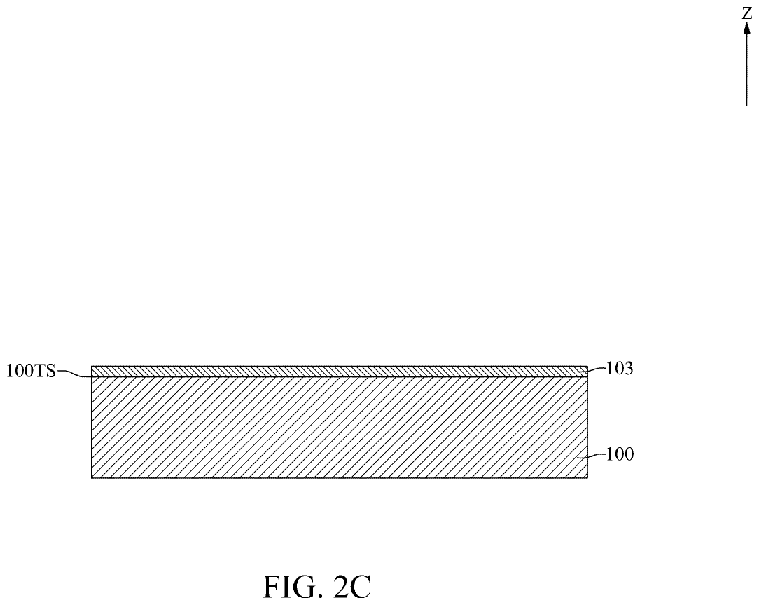

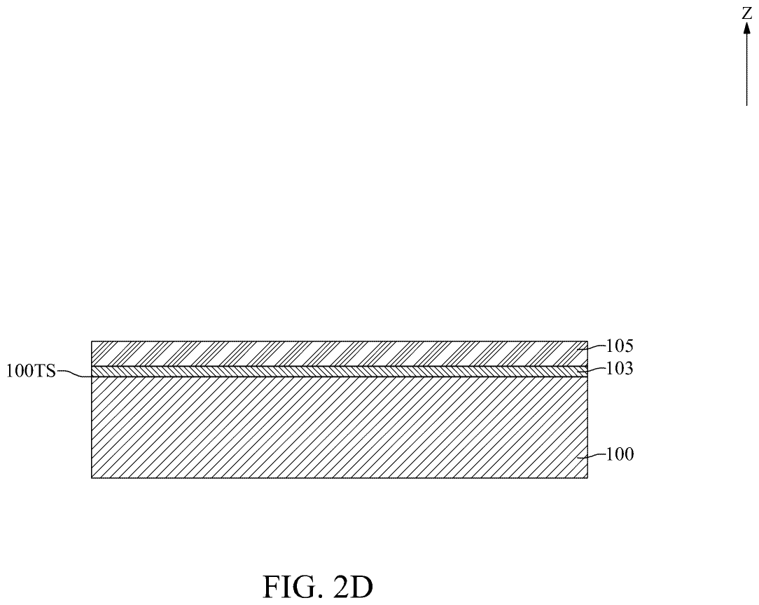

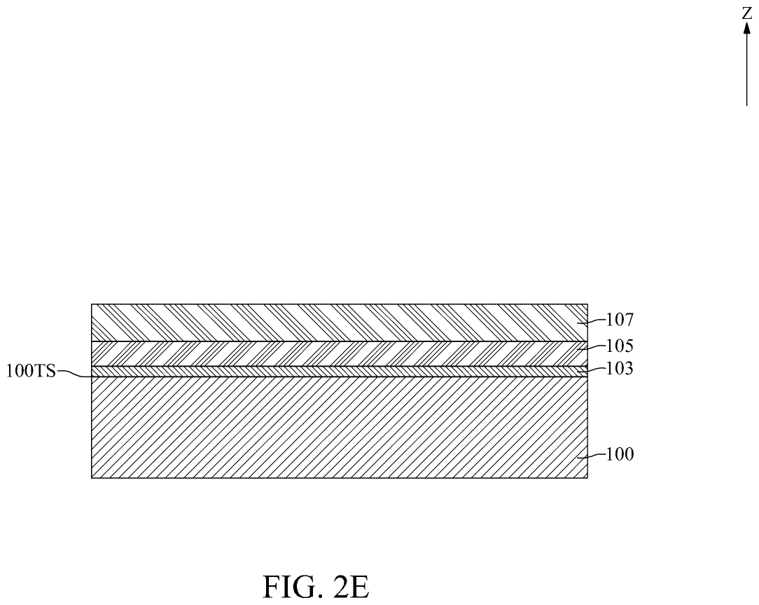

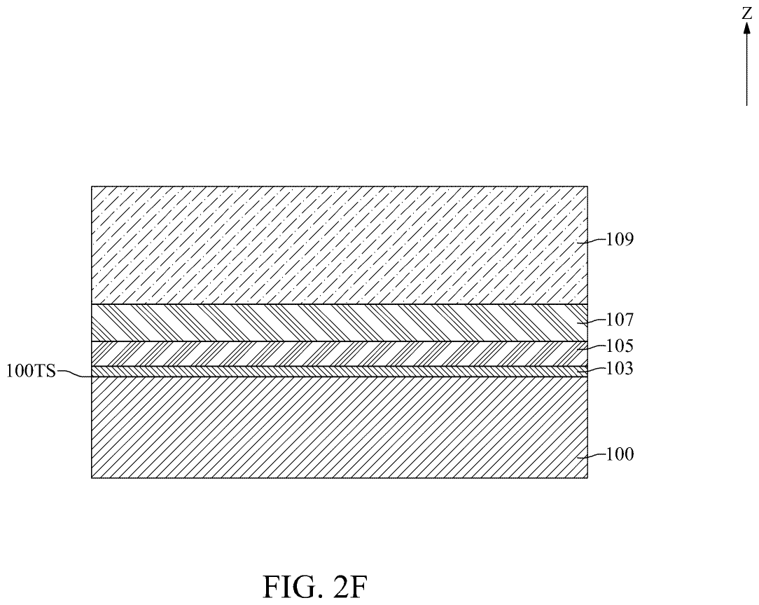

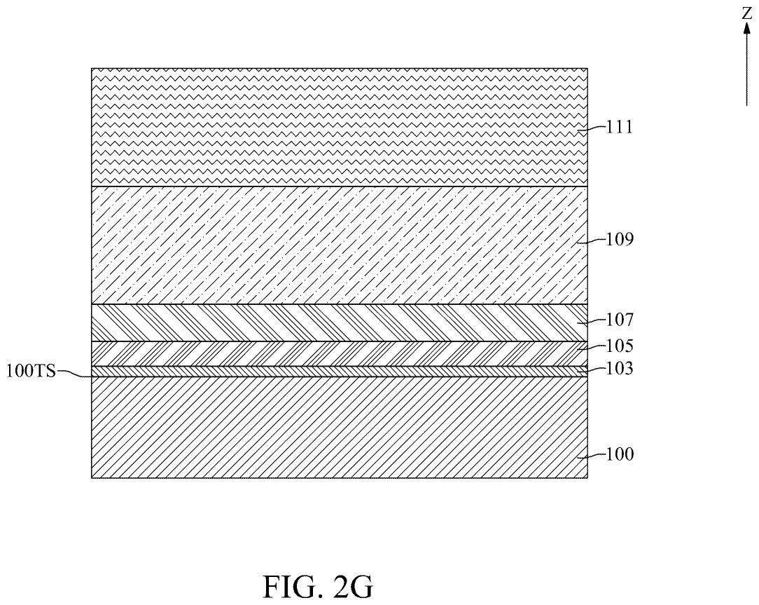

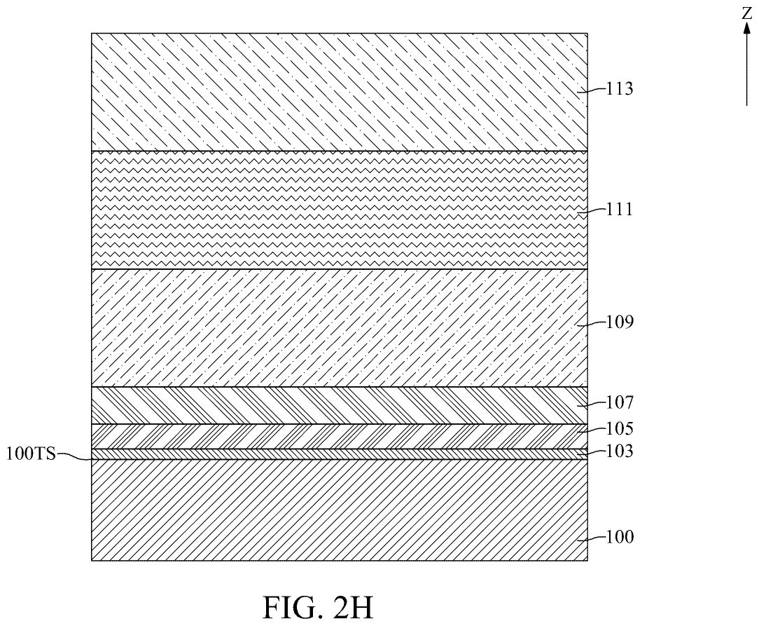

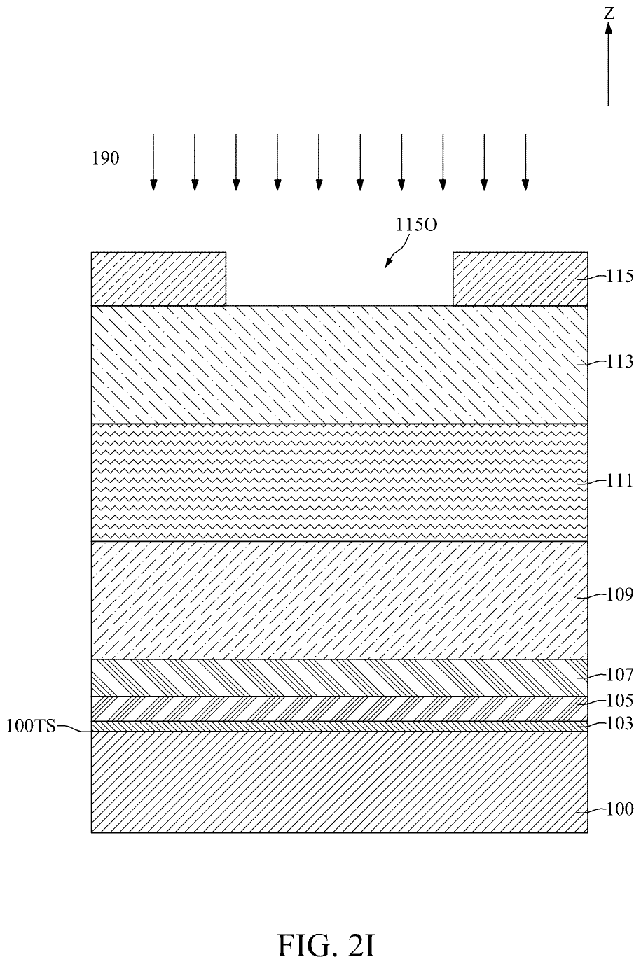

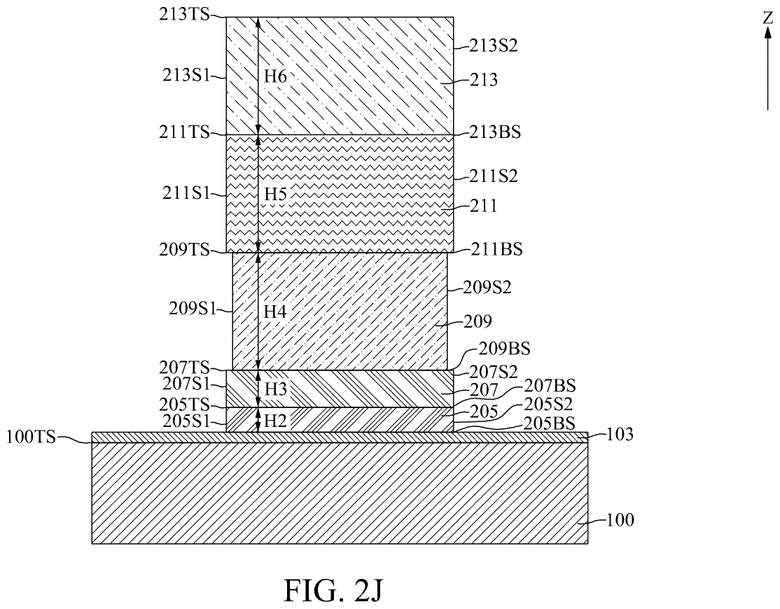

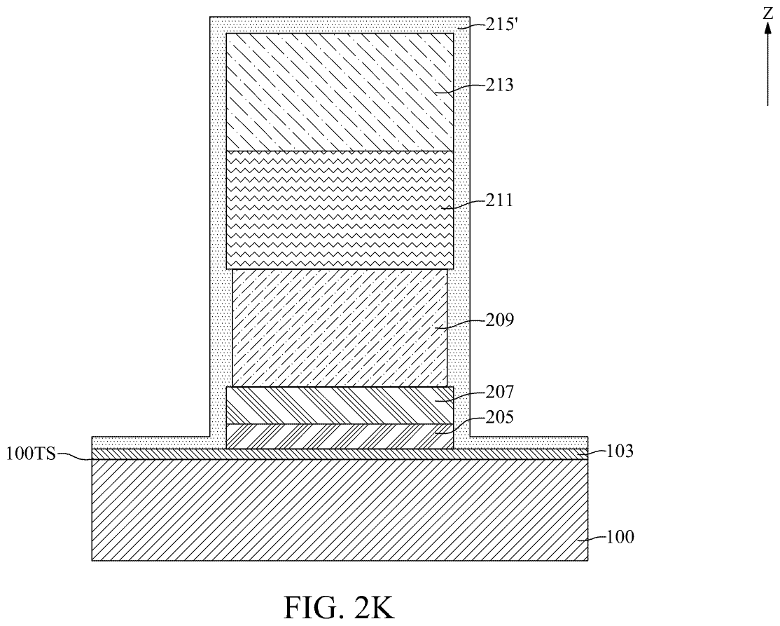

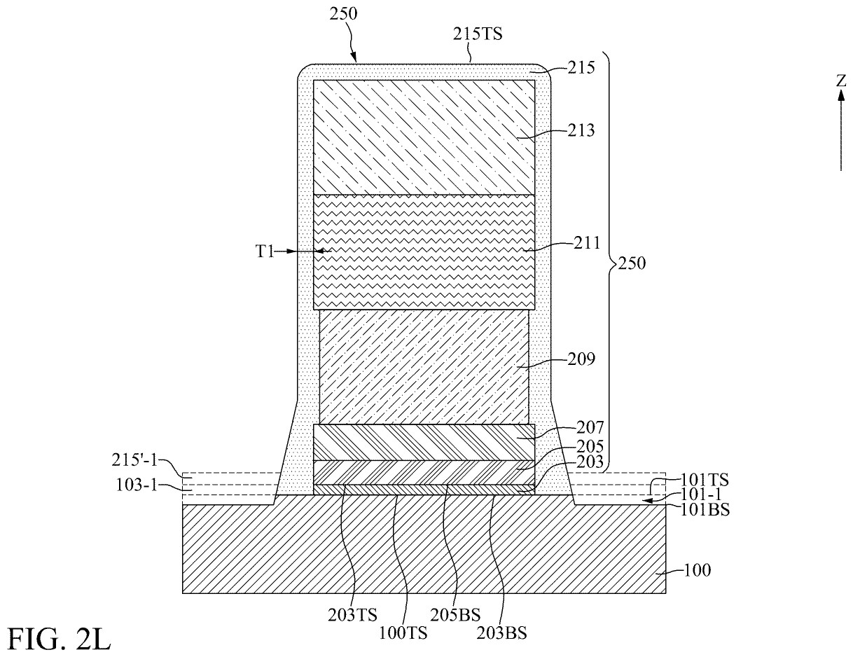

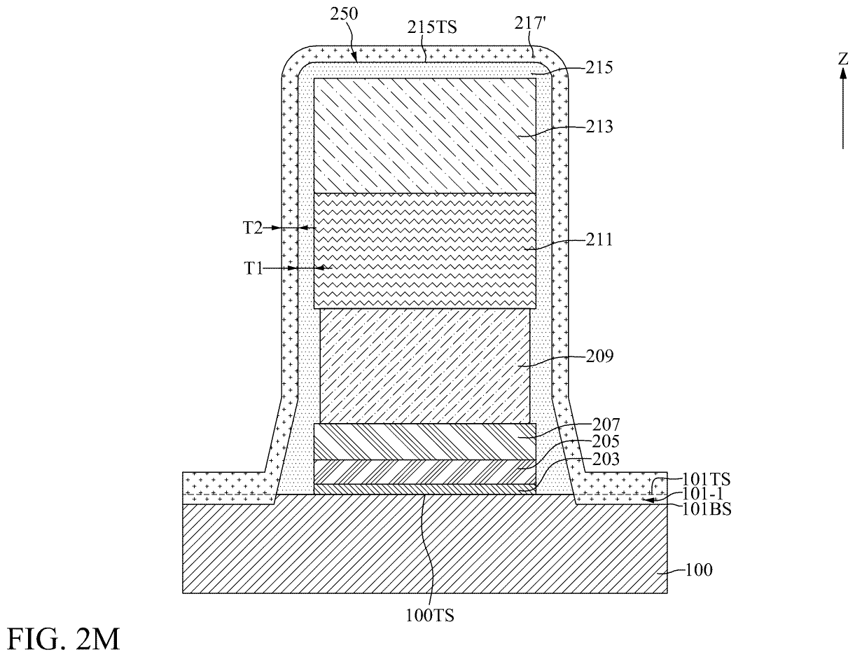

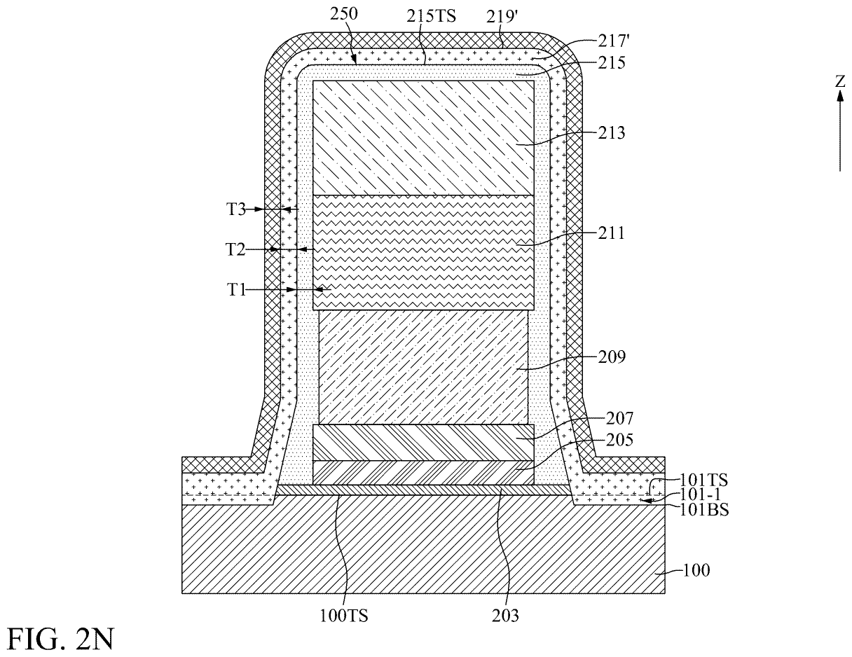

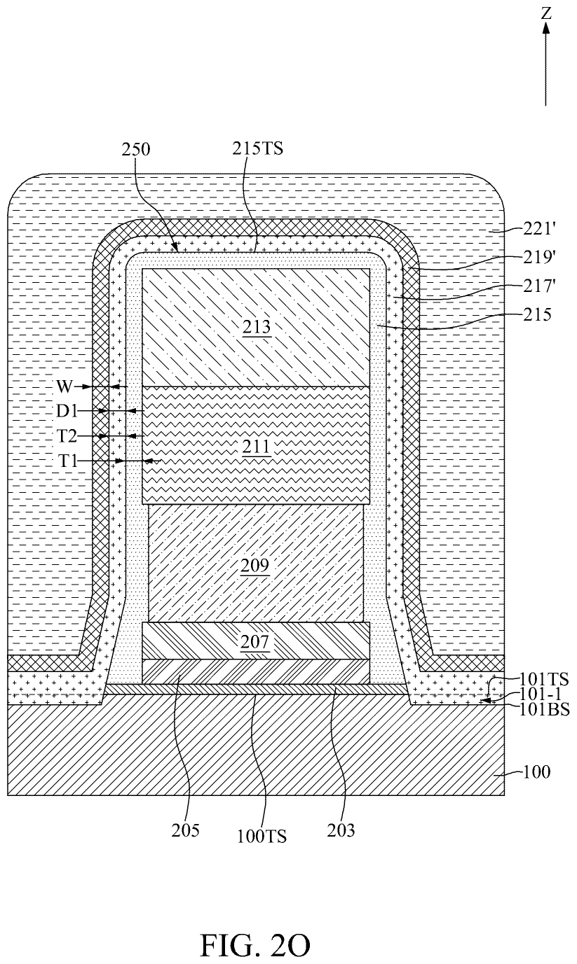

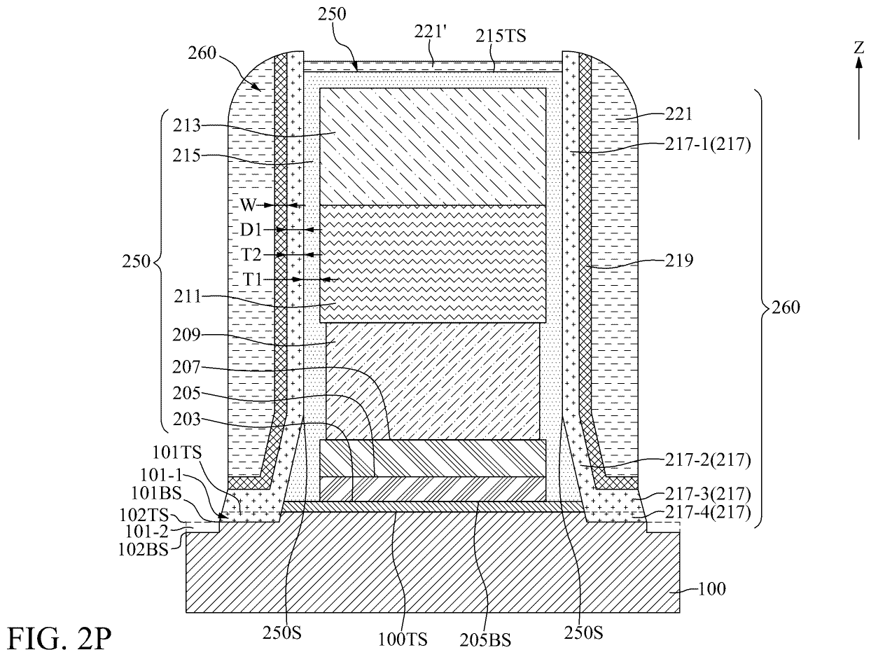

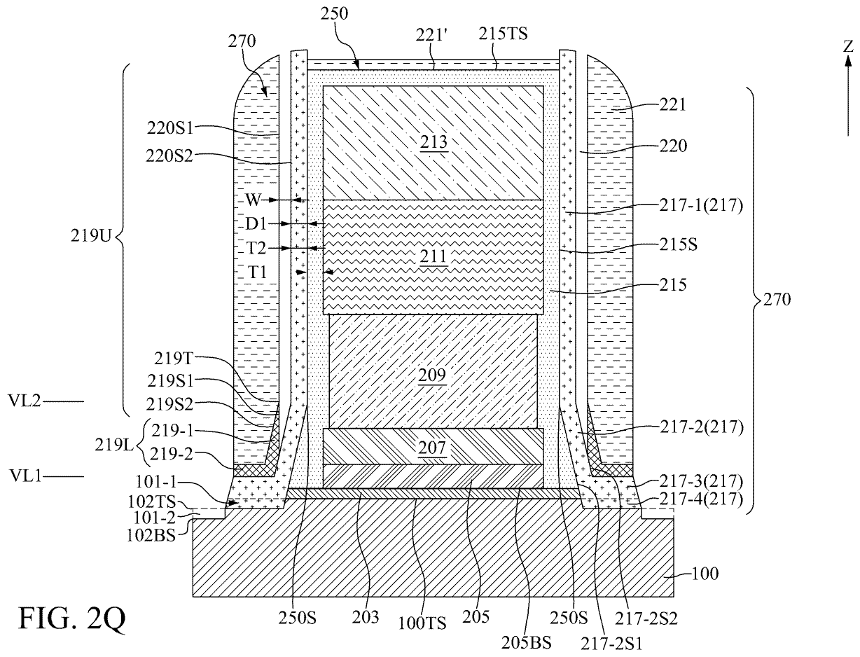

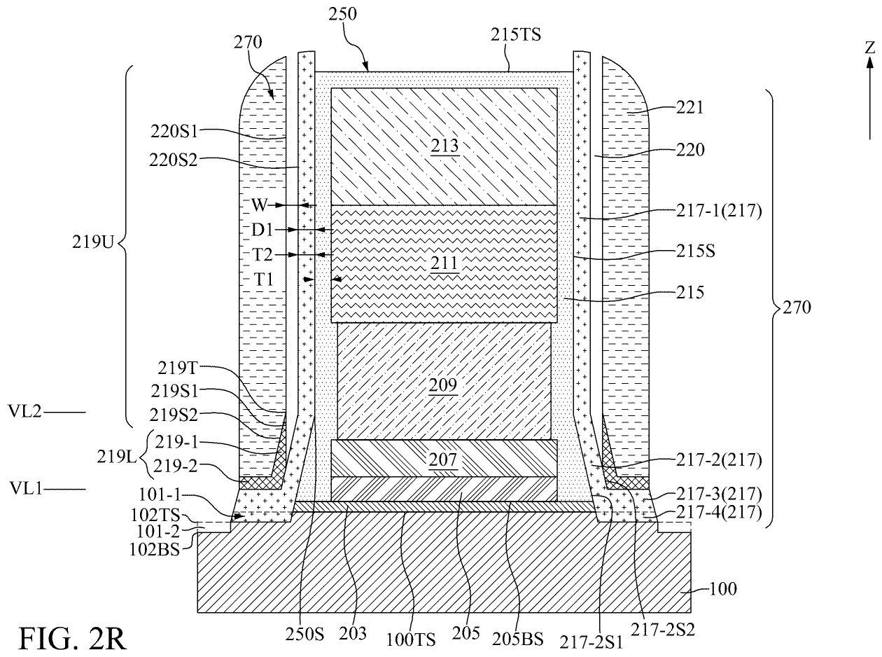

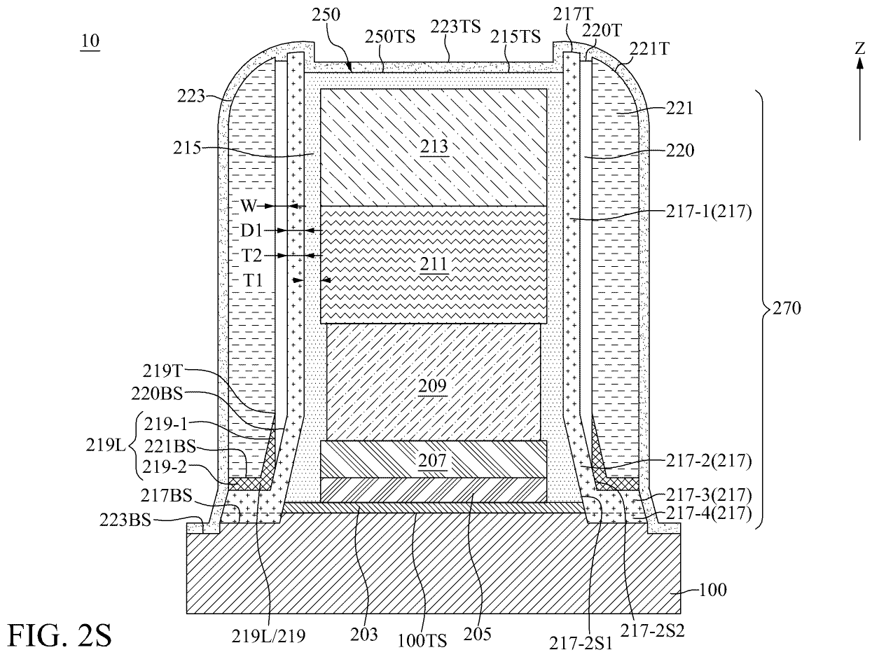

FIG. 2A is a flow diagram of a method 10a for fabricating a semiconductor device in accordance with some embodiments of the present disclosure. FIGS. 2B to 2S are schematic cross-sectional diagrams illustrating intermediate stages in accordance with the method 10a.

With reference to FIGS. 2A and 2B, in step S101, a substrate 100 may be provided. The substrate 100 may have a top surface 100TS.

In some embodiments, the substrate 100 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or another III-V compound semiconductor or II-VI compound semiconductor; or a combination thereof.

In some embodiments, the substrate 100 may include a semiconductor-on-insulator structure consisting of, from bottom to top, a handle substrate, an insulator layer, and a topmost semiconductor material layer. The handle substrate and the topmost semiconductor material layer may be formed of a material same as a material of the bulk semiconductor substrate mentioned above. The insulator layer may be a crystalline or non-crystalline dielectric material, such as an oxide and/or a nitride. For example, the insulator layer may be a dielectric oxide such as silicon oxide. Alternatively, the insulator layer may be a dielectric nitride such as silicon nitride or boron nitride. Additionally, the insulator layer may comprise a stack of a dielectric oxide and a dielectric nitride, such as a stack of silicon oxide, silicon nitride, and/or boron nitride, in any order.

With reference to FIG. 2A and FIGS. 2C to 2H, in step S103, dielectric materials 103 and 105, a metallic material 107, a metallic compound material 109, a metallic material 111, and a dielectric material 113 may be sequentially deposited over the top surface 100TS, covering the substrate 100.

With reference to FIG. 2C, the dielectric material 103 may be deposited over the substrate 100, covering the substrate 100. In some embodiments, the dielectric material 103 may be composed of a dielectric material such as silicon oxide, silicon nitride, silicon oxynitride, a low-k dielectric material, the like, or a combination thereof. The low-k dielectric material may have a dielectric constant less than 3.0 or even less than 2.5. In some embodiments, the low-k dielectric material may have a dielectric constant of less than 2.0. In some embodiments, the dielectric material 103 may be formed by a deposition process, such as a chemical vapor deposition (CVD) process, followed by an etching process, which may include isotropic etching, anisotropic etching, or a combination thereof. A CVD process temperature typically ranges from 600° C. to 1000° C., and a process pressure is usually equal to or less than one atmospheric pressure (1 atm).

With reference to FIG. 2D, the dielectric material 105 may be deposited over the dielectric material 103, covering the dielectric material 103. In some embodiments, the dielectric material 105 may be composed of a high-k dielectric material (e.g., a dielectric material having a dielectric constant greater than 3.9 or 7). The high-k dielectric material may include hafnium oxide, hafnium aluminum oxide, hafnium silicate, tantalum oxide, aluminum oxide, zirconium oxide, or a combination thereof. In some embodiments, the dielectric material 105 may be formed by a deposition process, such as an atomic layer deposition (ALD) process, followed by an etching process, which may include isotropic etching, anisotropic etching, or a combination thereof. An ALD process temperature typically ranges from 50° C. to 300° C., and a process pressure usually ranges from a few millitorr (mTorr) to several tens of torr (Torr).

With reference to FIG. 2E, the metallic material 107 may be deposited over the dielectric material 105, covering the dielectric material 105. In some embodiments, the metallic material 107 may be composed of a metallic material including tungsten, titanium, titanium nitride, aluminum, or a combination thereof. In some embodiments, the metallic material 107 may be formed by a deposition process and a subsequent etching process. The deposition process may include a physical vapor deposition (PVD) process, a chemical vapor deposition (CVD) process, an atomic layer deposition (ALD) process, or a combination thereof. The etching process may include isotropic etching, anisotropic etching, or a combination thereof.

With reference to FIG. 2F, the metallic compound material 109 may be deposited over the metallic material 107, effectively covering the metallic material 107. In some embodiments, the metallic compound material 109 can be composed of polysilicon, metal silicides (such as titanium silicide (TiSi₂) or cobalt silicide (CoSi₂)), polycide, or silicon carbide. The formation of the metallic compound material 109 may involve a deposition process, such as a chemical vapor deposition (CVD) process, followed by an etching process. The etching process may include isotropic etching, anisotropic etching, or a combination thereof.

With reference to FIG. 2G, the metallic material 111 may be deposited over the metallic compound material 109, effectively covering the metallic compound material 109. In some embodiments, the metallic material 111 may include tungsten, tantalum, aluminum, alloys such as aluminum-copper or tungsten-tantalum, or a combination thereof. The metallic material 111 may be formed using a deposition process, such as a physical vapor deposition (PVD) process, followed by an etching process that may include isotropic etching, anisotropic etching, or a combination thereof.

With reference to FIG. 2H, the dielectric material 113 may be deposited over the metallic material 111, effectively covering the metallic material 111. In some embodiments, the dielectric layer 113 may be composed of silicon nitride, silicon oxynitride, a low-k dielectric material, the like, or a combination thereof. The low-k dielectric material may have a dielectric constant of less than 3.0, and in some embodiments, less than 2.5, or even less than 2.0. The dielectric layer 113 may be formed using a deposition process, such as a chemical vapor deposition (CVD) process, followed by an etching process that may include isotropic etching, anisotropic etching, or a combination thereof.

With reference to FIGS. 2A, 2I and 2J, in step S105, a dielectric layer 205, a metallic layer 207, a metallic compound layer 209, a metallic layer 211, and a dielectric layer 213 may be formed.

With reference to FIG. 2I, a lithography process 190 using a photoresist 115 with an opening 115O as a mask may be performed on the dielectric material 105, the metallic material 107, the metallic compound material 109, the metallic material 111, and the dielectric material 113. In some embodiments, the lithography process 190 may include an exposure process, a development process, a post-bake process, and an etching process.

With reference to FIG. 2J, after the lithography process 190 is performed, the dielectric layer 205, the metallic layer 207, the metallic compound layer 209, the metallic layer 211, and the dielectric layer 213 may be formed. In some embodiments, the dielectric layer 205, the metallic layer 207, the metallic compound layer 209, the metallic layer 211, and the dielectric layer 213 may have thicknesses H2, H3, H4, H5, and H6, respectively. Additionally, a top surface 205TS of the dielectric layer 205 and a bottom surface 207BS of the metallic layer 207 may be substantially coplanar. Similarly, a top surface 207TS of the metallic layer 207 and a bottom surface 209BS of the metallic compound layer 209 may be substantially coplanar. A top surface 209TS of the metallic compound layer 209 and a bottom surface 211BS of the metallic layer 211 may be substantially coplanar, and a top surface 211TS of the metallic layer 211 and a bottom surface 213BS of the dielectric layer 213 may also be substantially coplanar.

A sidewall 213S1 of the dielectric layer 213 and a sidewall 211S1 of the metallic layer 211 may be substantially coplanar. Furthermore, a sidewall 213S2 of the dielectric layer 213 and a sidewall 211S2 of the metallic layer 211 may also be substantially coplanar. Additionally, a sidewall 205S1 of the dielectric layer 205 and a sidewall 207S1 of the metallic layer 207 may be substantially coplanar, and a sidewall 205S2 of the dielectric layer 205 and a sidewall 207S2 of the metallic layer 207 may be substantially coplanar.

With reference to FIGS. 2A, 2K, and 2L, in step S107, a dielectric layer 203 and a dielectric layer 215 may be formed over the substrate 100.

With reference to FIG. 2K, a dielectric material 215′ may be deposited to cover the dielectric material 203, the dielectric layer 205, the metallic layer 207, the metallic compound layer 209, the metallic layer 211, and the dielectric layer 213. In some embodiments, the dielectric layer 215′ may be composed of silicon nitride, silicon oxynitride, low-k dielectric materials, the like, or a combination thereof. The low-k dielectric materials may have a dielectric constant of less than 3.0, or even less than 2.5, with some embodiments specifying a dielectric constant of less than 2.0. The dielectric layer 215′ may be formed by a deposition process, such as a chemical vapor deposition (CVD) process, followed by an etching process that may include isotropic etchings, anisotropic etching, or a combination thereof.

With reference to FIG. 2L, an etching process, such as an isotropic etching process, may be performed to remove a portion 215′-1 of the dielectric material 215′ and a portion 103-1 of the dielectric material 103. After the etching process is performed, the dielectric layers 203 and 215 may be formed, with the dielectric layer 203 having a thickness of H1 and the dielectric layer 215 having a thickness of T1. In some embodiments, after the formation of the dielectric layers 203 and 215, a portion 101-1 of the substrate 100 may also be removed. Additionally, in some embodiments, a top surface 203TS of the dielectric layer 203 and a bottom surface 205BS of the dielectric layer 205 may be substantially coplanar. Furthermore, a bottom surface 203BS of the dielectric layer 203 and a top surface 100TS of the substrate 100 may also be substantially coplanar.

In some embodiments, the dielectric layer 203, the dielectric layer 205, the metallic layer 207, the metallic compound layer 209, the metallic layer 211, the dielectric layer 213 and the dielectric layer 215 together form the gate structure 250.

With reference to FIGS. 2A, 2M, 2N, and 2O, in step S109, dielectric materials 217′, 219′, and 221′ may be conformally and sequentially deposited to cover both the gate structure 250 and the substrate 100.

With reference to FIG. 2M, the dielectric material 217′ may be conformally deposited on both the gate structure 250 and the substrate 100. In some embodiments, the dielectric material 217′ may include silicon oxide, silicon nitride, silicon oxynitride, a low-k dielectric material, the like, or a combination thereof. A material of the dielectric material 217′ may be same as that of the dielectric layer 215 in some embodiments, while in other embodiments, materials of the dielectric material 217′ and the dielectric layer 215 may differ. The dielectric material 217′ may have a thickness of T2, which can determine a position of an air gap (e.g., an air gap 220) to be formed in a subsequent process. In some embodiments, the thickness T2 is positively correlated with the thickness T1; that is, an increase in the thickness T1 allows for a greater thickness T2, while a decrease in the thickness T2 results in a smaller thickness T1. The deposition may include a physical vapor deposition (PVD) process, a chemical vapor deposition (CVD) process, an atomic layer deposition (ALD) process, or a combination thereof.

With reference to FIG. 2N, the dielectric material 219′ may be conformally deposited on the dielectric material 217′. In some embodiments, a material of the dielectric material 219′ may be same as that of the dielectric layer 215. In some embodiments, the material of the dielectric material 219′ may be different from that of the dielectric material 217′. The dielectric material 219′ may have a thickness T3, which can determine a width of an air gap (e.g., the air gap 220) to be formed in a subsequent process. In some embodiments, the thickness T3 is positively correlated with a deposition rate of a sealing layer (e.g., the sealing layer 223); that is, an increase in the deposition rate allows for a greater thickness T3, while a decrease in the deposition rate results in a smaller thickness T3. The deposition process may include physical vapor deposition (PVD), chemical vapor deposition (CVD), atomic layer deposition (ALD), or a combination thereof.

With reference to FIG. 2O, the dielectric material 221′ may be conformally deposited on the dielectric material 219′. A material of the dielectric material 221′ may be same as that of the dielectric material 217′. In some embodiments, the material of the dielectric material 221′ may be different from that of the dielectric material 219′. The deposition process may include a physical vapor deposition (PVD) process, a chemical vapor deposition (CVD) process, an atomic layer deposition (ALD) process, or a combination thereof.

With reference to FIGS. 2A and 2P, in step S111, a spacer structure 260 may be formed on a sidewall 250S of the gate structure 250, located at the portion 101-1 of the substrate 100, which was removed in the previous etching process.

With reference to FIG. 2P, in some embodiments, a lithography process may be performed to remove portions of the dielectric materials 217′, 219′, and 221′, thereby forming spacers 217, 219, and 221, respectively. The lithography process may include a photoresist coating process, an exposure process, a development process, a post-bake process, and an etching process. Additionally, in some embodiments, after the formation of the spacer structure 260, a portion 101-2 of the substrate 100 may also be removed.

After the lithography process is performed, the spacer 219 may be sandwiched between the spacers 217 and 221. The spacer 217 may include a vertical portion 217-1, a slanted portion 217-2 connected to the vertical portion 217-1, and a horizontal portion 217-3 connected to the slanted portion 217-2. A portion 217-4 of the portion 217-3 may be located at the previously removed portion 101-1 of the substrate 100. In some embodiments, the spacers 217, 219, and 221 together form the spacer structure 260.

With reference to FIGS. 2A, 2Q, and 2R, in step S113, a spacer structure 270 may be formed.

With reference to FIG. 2Q, in some embodiments, an etching process, such as an anisotropic etching process, may be performed to remove an upper portion 219U of the spacer 219. For process control convenience, a material of the spacer 219 may have high etch selectivity relative to the materials of the spacers 217 and 221. For example, in some embodiments, during the etching process, a ratio of an etch rate of the spacer 219 to etch rates of the spacers 217 and 221 may be between about 100:1 and about 1.05:1, between about 50:1 and about 2:1, or between about 10:1 and about 2:1. In some embodiments, the etching process may continue until a surface (e.g., a surface 217-2S2) of the portion 217-2 of the spacer 217 is exposed.

After the etching process is performed, a lower portion 219L of the spacer 219 may remain in place, while the air gap 220 is formed. In some embodiments, the lower portion 219L may include a portion 219-1, located between the portion 217-2 of the spacer 217 and the spacer 221, and a portion 219-2, located between the portion 217-3 of the spacer 217 and the spacer 221, connecting to the portion 219-1. The portion 219-1 may be slanted and may include a topmost point 219T at a vertical level VL2, while the portion 219-2 may be horizontal and may be sandwiched between the spacers 217 and 221.

In some embodiments, the air gap 220 may be vertically disposed and sandwiched between the spacers 217, 221, connecting to the spacer 219L. In some embodiments, the air gap may feature a slanted bottom surface 220BS and a lowest point 220B located at a vertical level VL1. Additionally, a sidewall 220S1 of the air gap 220 and a sidewall 219S2 of the spacer 219 may be coplanar. Slanted bottom surface 220BS and a slanted sidewall 217-2 of the spacer 217 may also be coplanar. Furthermore, the vertical level VL1 of the lowest point 220B of the air gap 220 may be lower than the vertical level VL2 of the topmost point 219T of the spacer 219. Together, the air gap 220 and the spacers 217, 219, and 221 form the spacer structure 270.

With reference to FIG. 2R, after the air gap 200 is formed, a trimming process, such as a planarization process or an etching process, may be performed to remove a residual portion 221′P (see FIG. 2Q) of the dielectric material 221′ over the top surface 215T of the dielectric layer 215. In some embodiments, the trimming process may include an etch-back process and may be performed until the top surface 215T of the dielectric layer 215 is exposed.

With reference to FIGS. 2A and 2S, in step S115, a sealing layer 223 may be conformally deposited to cover the substrate 100, the gate structure 250, and the spacer structure 270.

With reference to FIG. 2S, in some embodiments, a material for the sealing layer 223, such as a nitride oxide, may be deposited on the substrate 100, the gate structure 250, and the spacer structure 270. The deposition process may include a physical vapor deposition (PVD) process, a chemical vapor deposition (CVD) process, an atomic layer deposition (ALD) process, or a combination thereof. In some embodiments, a high deposition rate is required to seal the air gap 220. The width W of the air gap 220 is positively correlated with the deposition rate of the sealing layer 223; that is, an increase in the deposition rate of the sealing layer 223 allows for a greater width W of the air gap 220, while a decrease in the deposition rate of the sealing layer 223 results in a smaller width W of the air gap 220. This design aims to prevent the sealing layer 223 from filling the air gap 220. Parameters of the deposition rate of the sealing layer 223 and the width W of the air gap 220 depend on design requirements of the process.

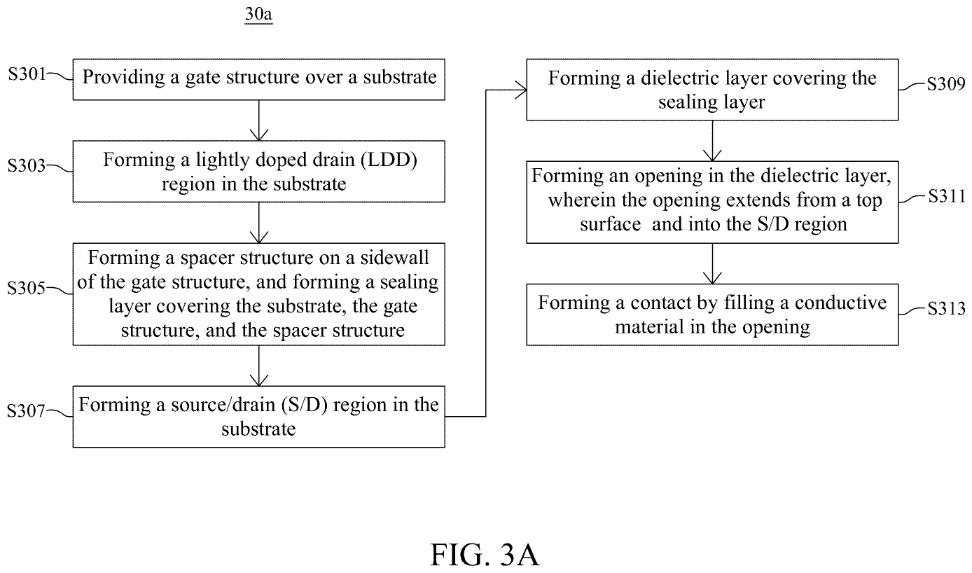

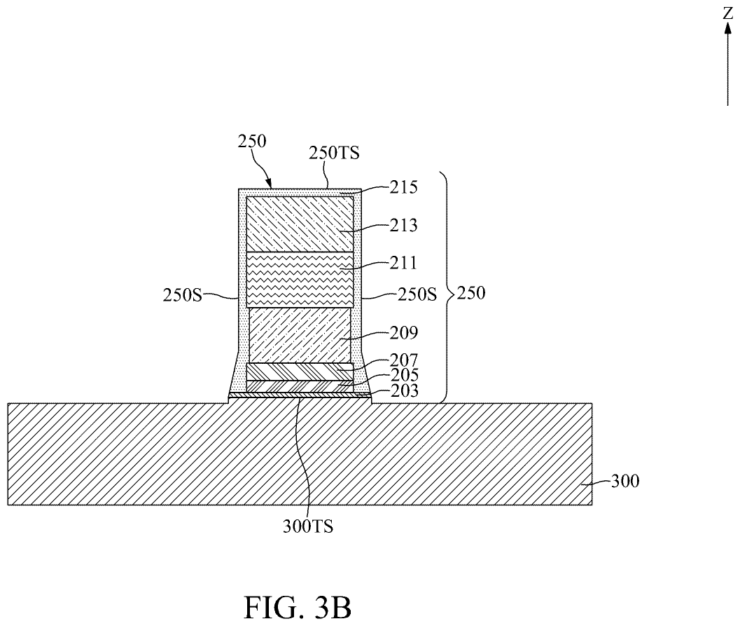

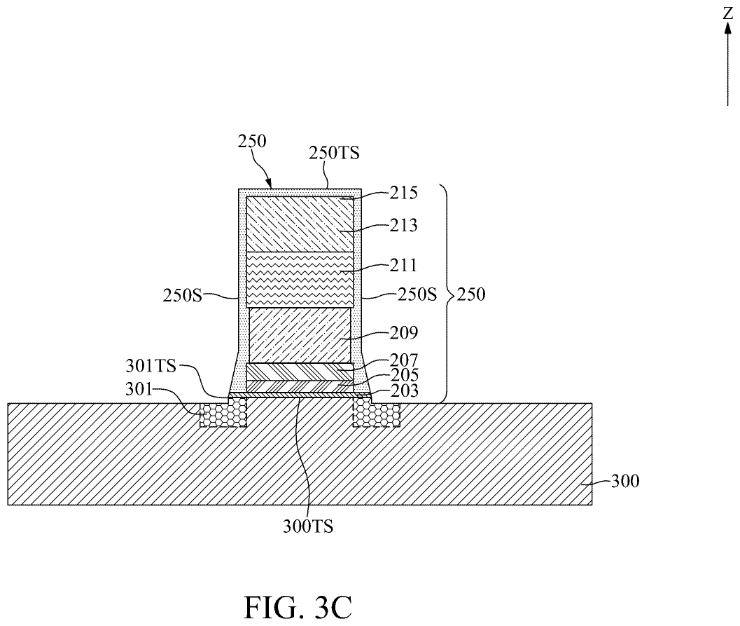

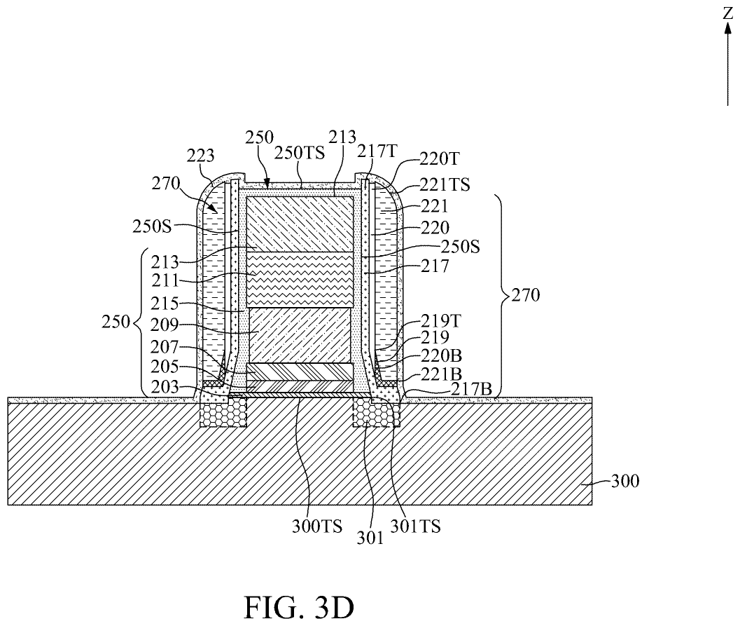

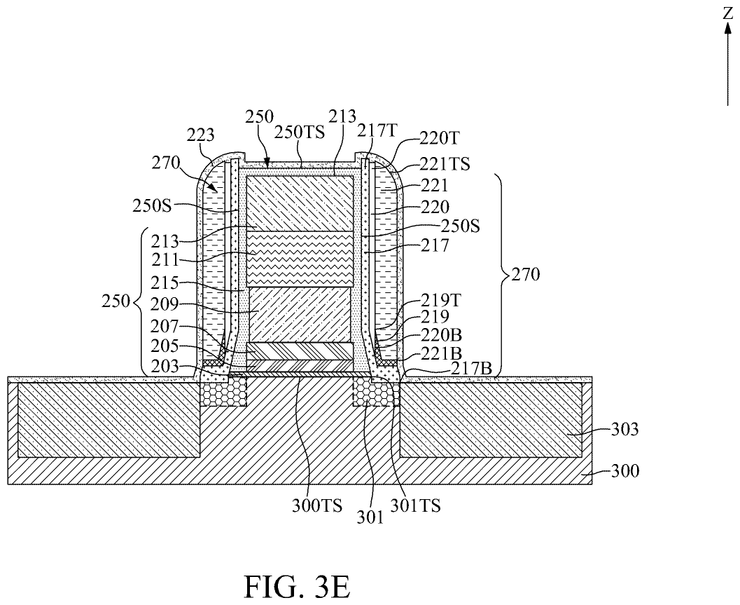

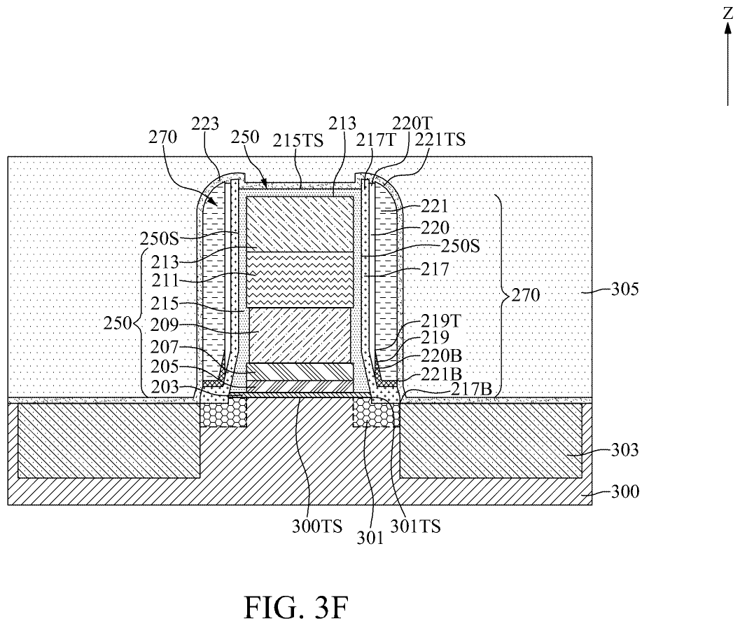

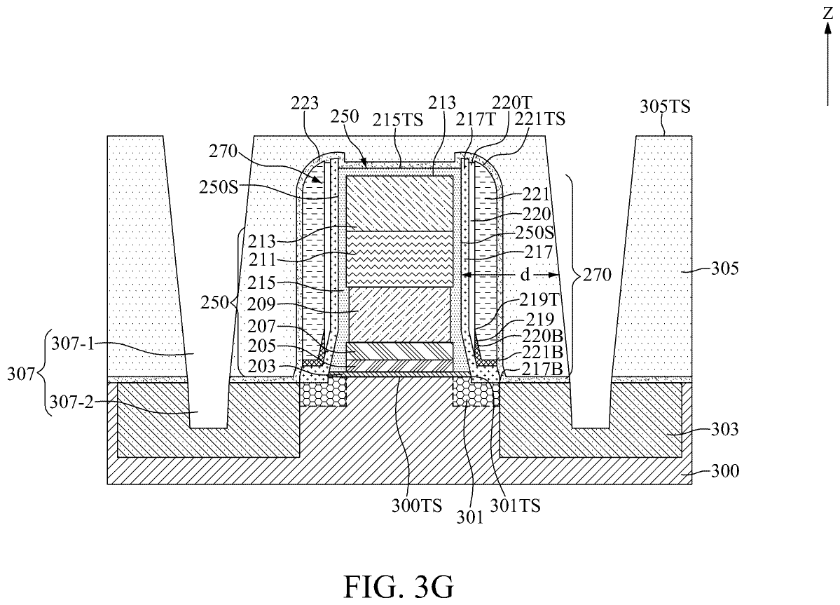

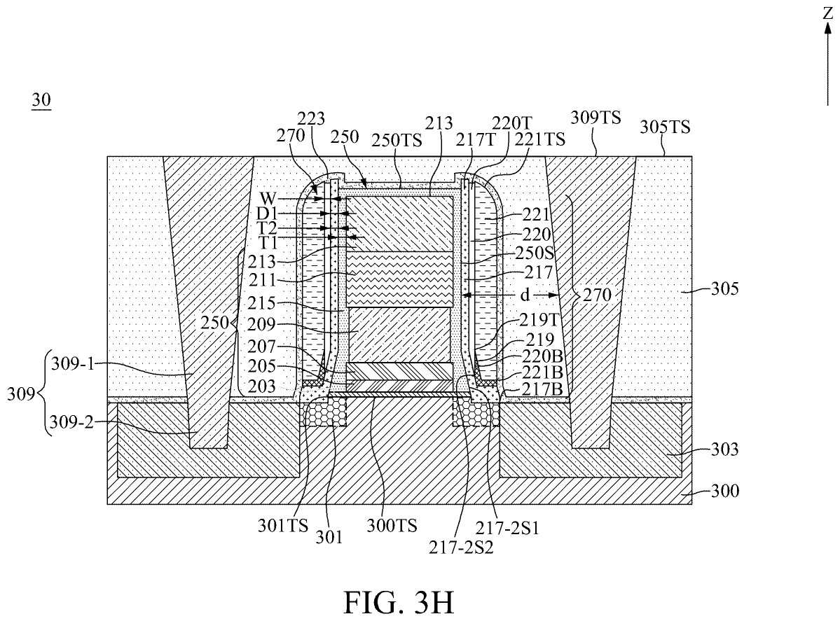

FIG. 3A is a flow diagram of a method 30a for fabricating a semiconductor structure in accordance with some embodiments of the present disclosure. FIGS. 3B to 3H are schematic cross-sectional diagrams illustrating intermediate stages in accordance with the method 30a.

With reference to FIGS. 3A and 3B, in step S301, a gate structure 250 may be provided over a substrate 300.

With reference to FIG. 3B, the gate structure 250 may be same as the gate structure 250 in FIG. 2L, and the substrate 300 may be same as the substrate 100 in FIG. 2B, and repeated descriptions are omitted.

With reference to FIGS. 3A and 3C, in step S303, a lightly doped drain (LDD) region 301 may be formed in the substrate 300.

With reference to FIG. 3C, in some embodiments, a doping process is performed to form the lightly doped drain (LDD) region 301. The LDD region 301 is typically located beneath the gate structure 250, near a drain region, and situated in a channel region between the drain region and source regions. In some embodiments, the LDD region 301 has a lower doping concentration compared to the source and drain regions, which is intended to reduce a strength of an electric field near the drain region. A choice of dopant used in the LDD region 301 depends on a type of MOSFET being formed. For example, in n-type MOSFETs, the substrate 300 is usually formed of n-type silicon, and the LDD region 301 utilizes lightly-doped n-type dopants such as phosphorus or arsenic. In contrast, in p-type MOSFETs, the substrate 300 is typically formed of p-type silicon, and the LDD region 301 employs lightly-doped p-type dopants such as boron.

With reference to FIGS. 3A and 3D, in step S305, a spacer structure 270 may be formed on a sidewall 250S of the gate structure 250, and a sealing layer 223 may be deposited to cover the substrate 300, the gate structure 250, and the spacer structure 270.

With reference to FIG. 3D, the spacer structure 270 and the sealing layer 223 may be same as the spacer structure 270 in FIGS. 2R and 2S, and repeated descriptions are omitted.

With reference to FIGS. 3A and 3E, in step S307, a source/drain (S/D) region 303 may be formed on a sidewall 250S of the gate structure 250.

With reference to FIG. 3E, in some embodiments, a doping process is performed to form the source/drain (S/D) region 303. The S/D region 303 is typically located near the lightly-doped drain (LDD) region 301, and in some embodiments, the two regions may partially overlap. A doping type of the S/D region 303 is generally same as that of the LDD region 301; however, a doping concentration in the S/D region 303 is typically higher than that in the LDD region 301. This indicates that dopants used in the LDD region 301 (such as phosphorus or boron) are present at a concentration lower than a concentration of dopants in the S/D region 303.

With reference to FIGS. 3A and 3F, in step S309, a dielectric layer 305 may be disposed to cover the sealing layer 223.

With reference to FIG. 3F, in some embodiments, a deposition process is performed to form the dielectric layer 305. The deposition process may include physical vapor deposition (PVD), chemical vapor deposition (CVD), atomic layer deposition (ALD), or a combination thereof. The dielectric layer 305 may consist of materials such as silicon oxide, silicon nitride, silicon oxynitride, organosilicate glass, polyimide, fluorinated silicate glass, or a combination thereof.

With reference to FIGS. 3A and 3G, in step S311, an opening 307 may be formed in the dielectric layer 305.

With reference to FIG. 3G, in some embodiments, the opening 307 may be formed using an etching process, such as isotropic etching, anisotropic etching, or a combination of thereof. The opening 307 is located on a side of the gate structure 250 and is spaced apart from the gate structure 250 by a distance d. In some embodiments, due to an etching selectivity in the etching process, excessive silicon consumption may occur during the etching of a contact window, causing the opening 307 to penetrate the dielectric layer 305 and extend into the source/drain (S/D) region 303. In some embodiments, the opening 307 may be separated from the gate structure 250 by the spacer structure 270 and the sealing layer 223. The opening 307 consists of an upper portion 307-1 located in the dielectric layer 305 and a lower portion 307-2 situated in the S/D region 303. Both the upper portion 307-1 and the lower portion 307-2 exhibit a tapered profile.

With reference to FIGS. 3A and 3H, in step S313, a contact 309 may be formed in the dielectric layer 305.

With reference to FIG. 3H, a material for the dielectric layer 305 may be deposited in the opening 307 using a chemical vapor deposition (CVD) method. In some embodiments, the material may include aluminum, copper, tungsten, cobalt, gold, silver, an alloy (such as an aluminum-copper alloy), or a combination thereof. After the deposition process is completed, the contact 309 can be formed, consisting of an upper portion 309-1 and a lower portion 309-2, which are respectively disposed in the upper portion 307-1 and the lower portion 307-2 of the opening 307. Since each of the upper portion 307-1 and the lower portion 307-2 of the opening 307 has a tapered profile, the upper portion 309-1 and the lower portion 309-2 of the contact 309 may also exhibit tapered profiles. After the formation of the contact 309, a planarization process may be performed to remove a portion of the dielectric layer 305 and a portion of the contact material 309, providing a substantially flat surface for subsequent processing.

Embodiments of the present disclosure provide a semiconductor device 10 that includes a spacer structure 270 comprising an air gap 200. Additionally, a method 10a is presented for utilizing the spacer structure 270 to reduce parasitic capacitance between a gate structure 250 and a contact. By applying the semiconductor device 10 and the associated method 10a, parasitic capacitance between the gate structure 250 and the contact is reduced, leading to improved gate control performance.

One aspect of the present disclosure provides a semiconductor device comprising a substrate with a top surface, a gate structure disposed on the top surface of the substrate, a spacer structure disposed on a sidewall of the gate structure, and a sealing layer covering the substrate, the spacer structure, and the gate structure. The spacer structure comprises a first spacer, a second spacer, a third spacer, and an air gap. The first spacer is disposed on the sidewall of the gate structure, and the air gap is located between the first spacer and the second spacer. The air gap is enclosed by the first spacer, the second spacer, the third spacer, and the sealing layer.

In some embodiments, the gate structure comprises a first dielectric layer disposed on the top surface of the substrate, a metallic compound layer disposed over the first dielectric layer, a second metallic layer disposed over the metallic compound layer, a third dielectric layer disposed on the second metallic layer, and a fourth dielectric layer covering the first dielectric layer, the metallic compound layer, the second metallic layer, and the third dielectric layer.

In some embodiments, the first dielectric layer includes silicon oxide; the metallic compound layer includes polysilicon; the second metallic layer includes tungsten; the third dielectric layer includes silicon nitride; and the fourth dielectric layer also includes silicon nitride.

In some embodiments, the semiconductor device further comprises a second dielectric layer disposed between the first dielectric layer and the metallic compound layer, and a first metallic layer disposed between the second dielectric layer and the metallic compound layer.

In some embodiments, the fourth dielectric layer further covers the second dielectric layer and the first metallic layer.

In some embodiments, the second dielectric layer includes hafnium oxide, hafnium aluminum oxide, hafnium silicate, tantalum oxide, aluminum oxide, zirconium oxide, the like, or a combination thereof; and the first metallic layer includes tungsten, aluminum, tantalum, titanium, platinum, nickel, or an alloy or a combination thereof.

In some embodiments, the air gap is sealed by the sealing layer.

In some embodiments, the air gap comprises a slanted bottom surface.

In some embodiments, the slanted bottom surface is coplanar with a slanted sidewall of the first spacer.

In some embodiments, a vertical sidewall of the air gap is coplanar with a vertical sidewall of the second spacer and a vertical sidewall of the third spacer.

In some embodiments, a lowest point of the air gap is located at a vertical level lower than a vertical level of a topmost point of the third spacer.

In some embodiments, the sealing layer includes silicon nitride.

In some embodiments, a distance between the air gap and gate structure is positively correlated with a thickness of the fourth dielectric layer.

Another aspect of the present disclosure provides a semiconductor structure, comprising a substrate including a lightly doped drain (LDD) region disposed in a top surface of the substrate and a source/drain (S/D) region disposed in the substrate and adjacent to the LDD region; a gate structure disposed on the substrate; a spacer structure disposed on a sidewall of the gate structure; a sealing layer covering the substrate, the spacer structure, and the gate structure; a dielectric layer disposed covering the sealing layer; and a contact disposed in the dielectric layer and extending into the S/D region. The spacer structure comprises a first spacer, a second spacer, a third spacer, and an air gap. The air gap is disposed between the first spacer and the second spacer. The air gap is sealed by the sealing layer. The air gap is enclosed by the first spacer, the second spacer, the third spacer, and the sealing layer.

In some embodiments, the gate structure comprises a first dielectric layer disposed on the top surface of the substrate, a second dielectric layer disposed over the first dielectric layer, a first metallic layer disposed over the second dielectric layer, a metallic compound layer disposed over the first dielectric layer, a second metallic layer disposed over the metallic compound layer, a third dielectric layer disposed on the second metallic layer, and a fourth dielectric layer disposed covering the first dielectric layer, the first metallic layer, the second dielectric layer, the metallic compound layer, the second metallic layer and the third dielectric layer.

In some embodiments, the second dielectric layer includes hafnium oxide, hafnium aluminum oxide, hafnium silicate, tantalum oxide, aluminum oxide, zirconium oxide, the like, or a combination thereof; and the first metallic layer includes tungsten, aluminum, tantalum, titanium, platinum, nickel, or an alloy or a combination thereof.

In some embodiments, the air gap comprises a slanted bottom surface.

In some embodiments, the slanted bottom surface is coplanar with a slanted sidewall of the first spacer.

In some embodiments, a vertical sidewall of the air gap is coplanar with a vertical side surface of the second spacer and a vertical sidewall of the third spacer.

In some embodiments, a lowest point of the air gap is located at a vertical level lower than a vertical level of a topmost point of the third spacer.

In some embodiments, a distance between the air gap and the gate structure is positively correlated with a thickness of the fourth dielectric layer.

Another aspect of the present disclosure provides a method for fabricating a semiconductor device comprising providing a substrate; sequentially depositing a first dielectric material, a second dielectric material, a first metallic layer, a metallic compound material, a second metallic material, and a third dielectric material over and covering the substrate; performing a lithography process using a photoresist as a mask on the second dielectric material, the first metallic material, the metallic compound material, the second metallic material, and the third dielectric material, thereby forming a second dielectric layer, a first metallic layer, a metallic compound layer, a second metallic layer, and a third dielectric layer, respectively; depositing a fourth dielectric material covering the first dielectric material, the second dielectric layer, the first metallic layer, the metallic compound layer, the second metallic layer, and the third dielectric layer; forming a first dielectric layer and a fourth dielectric layer, wherein the first dielectric layer, the second dielectric layer, the first metallic layer, the metallic compound layer, the second metallic layer, the third dielectric layer, and the fourth dielectric layer together configure a gate structure; conformally forming a fifth dielectric material over the fourth dielectric layer and the substrate; forming a sixth dielectric material over the fifth dielectric material; forming a seventh dielectric material over the sixth dielectric material; forming a first spacer structure on a sidewall of the gate structure, wherein the first spacer structure comprises a first spacer, a second spacer, and a third spacer, with the third spacer sandwiched between the first spacer and the second spacer; forming a second spacer structure on the sidewall of the gate structure by removing an upper portion of the first spacer structure; and conformally forming a sealing layer over the substrate, the second spacer structure, and the gate structure, wherein the sealing layer seals the air gap.

In some embodiments, prior to the formation of the sealing layer, the method further comprises performing a trimming process to remove a residual portion of the seventh dielectric material over the gate structure.

In some embodiments, the trimming process comprises an etch-back process.

In some embodiments, the second dielectric material includes hafnium oxide, hafnium aluminum oxide, hafnium silicate, tantalum oxide, aluminum oxide, zirconium oxide, the like, or a combination thereof.

In some embodiments, the formation of the second dielectric material is performed by an atomic layer deposition process.

In some embodiments, a thickness of the fifth dielectric material is positively correlated with a thickness of the fourth dielectric layer.

In some embodiments, a thickness of the sixth dielectric material is positively correlated with a deposition rate of the sealing layer.

Another aspect of the present disclosure provides a method for fabricating a semiconductor structure comprising providing a gate structure over a substrate; forming a lightly doped drain (LDD) region in the substrate; forming a spacer structure on a sidewall of the gate structure; forming a source/drain (S/D) region in the substrate; forming a dielectric layer covering the spacer structure and the gate structure; forming an opening in the dielectric layer, wherein the opening extends from a top surface and into the S/D region; and forming a contact by depositing a conductive material in the opening. In some embodiments, the LDD region and the S/D region are formed by an ion implantation process.

In some embodiments, the contact is separated from the gate structure by the spacer structure.

Embodiments of the present disclosure provide a semiconductor device that includes a spacer structure comprising an air gap. Additionally, a method is presented for utilizing the spacer structure to reduce parasitic capacitance between a gate and a contact. By applying the semiconductor device and the associated method, parasitic capacitance between the gate and the contact is reduced, leading to improved gate performance.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate with a top surface;
a gate structure disposed on the top surface of the substrate;
a spacer structure disposed on a sidewall of the gate structure; and
a sealing layer covering the substrate, the spacer structure, and the gate structure;
wherein the spacer structure comprises a first spacer, a second spacer, a third spacer, and an air gap;
wherein the first spacer is disposed on the sidewall of the gate structure, and the air gap is located between the first spacer and the second spacer,
wherein the air gap is enclosed by the first spacer, the second spacer, the third spacer, and the sealing layer.

2. The semiconductor device of claim 1, wherein the gate structure comprises:
a first dielectric layer disposed on the top surface of the substrate;
a metallic compound layer disposed over the first dielectric layer;
a second metallic layer disposed over the metallic compound layer;
a third dielectric layer disposed on the second metallic layer; and
a fourth dielectric layer covering the first dielectric layer, the metallic compound layer, the second metallic layer, and the third dielectric layer.

3. The semiconductor device of claim 2, wherein the first dielectric layer includes silicon oxide; the metallic compound layer includes polysilicon; the second metallic layer includes tungsten; the third dielectric layer includes silicon nitride; and the fourth dielectric layer also includes silicon nitride.

4. The semiconductor device of claim 2, further comprising:
a second dielectric layer disposed between the first dielectric layer and the metallic compound layer; and
a first metallic layer disposed between the second dielectric layer and the metallic compound layer.

5. The semiconductor device of claim 4, wherein the fourth dielectric layer further covers the second dielectric layer and the first metallic layer.

6. The semiconductor device of claim 4, wherein the second dielectric layer includes hafnium oxide, hafnium aluminum oxide, hafnium silicate, tantalum oxide, aluminum oxide, zirconium oxide, the like, or a combination thereof; and the first metallic layer includes tungsten, aluminum, tantalum, titanium, platinum, nickel, or an alloy or a combination thereof.

7. The semiconductor device of claim 1, wherein the air gap is sealed by the sealing layer.

8. The semiconductor device of claim 1, wherein the air gap comprises a slanted bottom surface.

9. The semiconductor device of claim 8, wherein the slanted bottom surface is coplanar with a slanted sidewall of the first spacer.

10. The semiconductor device of claim 9, wherein a vertical sidewall of the air gap is coplanar with a vertical sidewall of the second spacer and a vertical sidewall of the third spacer.

11. The semiconductor device of claim 10, wherein a lowest point of the air gap is located at a vertical level lower than a vertical level of a topmost point of the third spacer.

12. The semiconductor device of claim 1, wherein the sealing layer includes silicon nitride.

13. The semiconductor device of claim 2, wherein a distance between the air gap and the gate structure is positively correlated with a thickness of the fourth dielectric layer.
